(19) United States
(12) Patent Application Publication
(10) Pub. No.: US 2024/0353217 A1
(43) Pub. Date: Oct. 24, 2024

(54) SHOWERHEAD TO PEDESTAL GAPPING WITH DIFFERENTIAL CAPACITIVE SENSOR SUBSTRATE

(71) Applicant: LAM RESEARCH CORPORATION, Fremont, CA (US)

(72) Inventors: Jacob L. HIESTER, Newberg, OR (US); Richard BLANK, San Jose, CA (US)

(21) Appl. No.: 18/684,086

(22) PCT Filed: Aug. 2, 2022
(86) PCT No.: PCT/US2022/039100

§ 371 Date: Feb. 15, 2024

Related U.S. Application Data
(60) Provisional application No. 63/233,516, filed on Aug. 16, 2021.

(51) Int. Cl. G01B 7/14; C23C 16/507; C23C 16/52; H01L 21/67

(52) U.S. Cl. CPC G01B 7/14; C23C 16/507; C23C 16/52; H01L 21/67259

(57) ABSTRACT

A sensor disc configured to measure a gap between a first structure and a second structure in a processing chamber of a substrate processing system includes an upper surface, at least one first capacitive sensor arranged on the upper surface of the sensor disc that is configured to generate a first measurement signal indicative of a first distance between the upper surface of the sensor disc and the first structure, a lower surface, and at least one second capacitive sensor arranged on the lower surface of the sensor disc that is configured to generate a second measurement signal indicative of a second distance between the lower surface of the sensor disc and the second structure.

### CROSS-REFERENCE TO RELATED APPLICATIONS

This application claims the benefit of U.S. Provisional Application No. 63/233,516, filed on Aug. 16, 2021. The entire disclosure of the application referenced above is incorporated herein by reference.

### FIELD

The present disclosure relates to test substrates for substrate processing systems, and more particularly to test substrates including capacitive sensors.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support (e.g., a pedestal) and one or more precursor gases may be supplied to a processing chamber using a gas distribution device (e.g., a showerhead) during one or more process steps. In a PECVD or PEALD process, plasma is used to activate chemical reactions within the processing chamber during deposition.

### SUMMARY

A sensor disc configured to measure a gap between a first structure and a second structure in a processing chamber of a substrate processing system includes an upper surface, at least one first capacitive sensor arranged on the upper surface of the sensor disc that is configured to generate a first measurement signal indicative of a first distance between the upper surface of the sensor disc and the first structure, a lower surface, and at least one second capacitive sensor arranged on the lower surface of the sensor disc that is configured to generate a second measurement signal indicative of a second distance between the lower surface of the sensor disc and the second structure.

In other features, the at least one first capacitive sensor includes three capacitive sensors arranged on the upper surface of the sensor disc. The at least one second capacitive sensor includes three capacitive sensors arranged on the lower surface of the sensor disc. The at least one first capacitive sensor is configured to form a first capacitor with the first structure and generate the first measurement signal based on a first capacitance of the first capacitor. The at least one second capacitive sensor is configured to form a second capacitor with the second structure and generate the second measurement signal based on a second capacitance of the second capacitor. The sensor disc further includes a recessed region defined in the lower surface of the sensor disc. The recessed region extends from an outer edge to a central region of the sensor disc.

In other features, a system includes the sensor disc and further includes a controller configured to receive the first measurement signal and the second measurement signal and calculate a width of the gap between the first structure and the second structure based on the first measurement signal and the second measurement signal. The controller is configured to calculate the width of the gap based on the first distance, the second distance, and a thickness of the sensor disc. The controller is configured to calculate the width of the gap further based on stored data correlating a first capacitance formed between the at least one first capacitive sensor and the first structure to the first distance and correlating a second capacitance formed between the at least one second capacitive sensor and the second structure to the second distance. The first structure is a showerhead and the second structure is a pedestal.

A system configured to measure a gap between a first structure and a second structure in a processing chamber of a substrate processing system includes a sensor disc including at least one first capacitive sensor arranged on an upper surface of the sensor disc and at least one second capacitive sensor arranged on a lower surface of the sensor disc and a controller configured to receive, from the at least one first capacitive sensor, a first measurement signal indicative of a first distance between the upper surface of the sensor disc and the first structure, receive, from the at least one second capacitive sensor, a second measurement signal indicative of a second distance between the lower surface of the sensor disc and the second structure, and calculate a width of the gap between the first structure and the second structure based on the first measurement signal and the second measurement signal.

In other features, the controller is configured to calculate the width of the gap based on the first distance, the second distance, and a thickness of the sensor disc. The controller is configured to calculate the width of the gap further based on stored data correlating a first capacitance formed between the at least one first capacitive sensor and the first structure to the first distance and correlating a second capacitance formed between the at least one second capacitive sensor and the second structure to the second distance. A recessed region is defined in the lower surface of the sensor disc, and wherein the recessed region extends from an outer edge to a central region of the sensor disc. The system further includes a mechanical indexer including an end effector and the recessed region is configured to receive the end effector.

A method for measuring a gap between a first structure and a second structure in a processing chamber of a substrate processing system includes arranging a sensor disc on an end effector, positioning the sensor disc in the gap between the first structure and the second structure, determining, using the sensor disc, a first distance between an upper surface of the sensor disc and the first structure and a second distance between a lower surface of the sensor disc and the second structure, and calculating a width of the gap between the first structure and the second structure based on the first distance and the second distance.

In other features, the sensor disc includes at least one first capacitive sensor arranged on an upper surface of the sensor disc and at least one second capacitive sensor arranged on a lower surface of the sensor disc. The method further includes generating, using the at least one first capacitive sensor, a first measurement signal indicative of the first distance between the upper surface of the sensor disc and the first structure, generating, using the at least one second capacitive sensor, a second measurement signal indicative of the second distance between the lower surface of the sensor disc and the second structure, and calculating the width of the gap between the first structure and the second structure based on the first measurement signal, the second measurement signal, and a thickness of the sensor disc.

In other features, the method further includes generating the first measurement signal based on a first capacitance formed between the at least one first capacitive sensor and the first structure and generating the second measurement signal based on a second capacitance formed between the at least one second capacitive sensor and the second structure. The sensor disc includes a recessed region defined in the lower surface of the sensor disc, the recessed region extends from an outer edge to a central region of the sensor disc, and arranging the sensor disc on the end effector includes arranging the recessed region of the sensor disc on the end effector. Positioning the sensor disc includes positioning the sensor disc at a midpoint between the first structure and the second structure. The first structure is a showerhead and the second structure is a pedestal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an embodiment of a substrate processing system according to the present disclosure;

FIG. 2A is an embodiment of a sensor disc according to the present disclosure;

FIG. 2B is an isometric view of an upper surface of the sensor disc of FIG. 2A;

FIG. 2C is an isometric view of a lower surface of the sensor disc of FIG. 2A;

FIG. 2D is another embodiment of a sensor disc according to the present disclosure; and

FIG. 3 is an embodiment of a method of determining a distance between a showerhead and a pedestal using a sensor disc according to the present disclosure.

In the drawings, reference numbers may be reused to identify similar and/or identical elements.

### DETAILED DESCRIPTION

A gap is defined between lower surface of a gas distribution device (e.g., a showerhead) and an upper surface of a substrate support (e.g., a pedestal). Substrate processing parameters (e.g., deposition rates, a plasma profile, etc.) may vary based on characteristics of the gap. Characteristics of the gap that may affect processing parameters include a width of the gap (i.e., a vertical distance between the showerhead and the substrate support) and variations in the width in a horizontal direction (e.g., variations caused by a tilted showerhead or substrate support surface).

Various methods may be used to measure the gap. The showerhead and the substrate may be adjusted based on the measurements to achieve a desired gap width and orientation. For example, showerhead tilt (i.e., level) and height and substrate support height may be adjustable. In some embodiments, a sensor disc or wafer may be arranged on the substrate support. One or more capacitive sensors are arranged on an upper surface of the sensor disc (i.e., on a showerhead-facing surface of the sensor disc).

The capacitive sensors are configured to measure a distance between the upper surface of the sensor disc and the showerhead. For example, as the distance changes, a capacitance detected by the capacitive sensors changes. The capacitive sensors generate measurement signals indicative of the capacitance and corresponding distance, which may then be used to determine the width of the gap. The capacitive sensors may be calibrated in accordance with a known distance (e.g., a known distance for a given material). As the distance between the capacitive sensors and the showerhead increases, the accuracy of the measurement signals decreases. For example, the accuracy of the measurement signals may experience an exponential decay relative to distance.

A sensor disc or substrate according to some embodiments of the present disclosure includes sensors, such as capacitive sensors, on both upper (i.e., showerhead-facing) and lower (i.e., substrate support-facing) surfaces. The sensor disc is positioned between an upper surface or other structure of a processing chamber (e.g., a gas distribution device, such as a showerhead) and the substrate support (e.g., on an end effector of a spindle, robot arm, etc.) without contacting either the showerhead or the substrate support. For example, the sensor disc may be positioned and suspended at a midpoint between the showerhead and the substrate support.

Accordingly, the sensors arranged on the upper surface of the sensor disc are configured to measure a first distance between the sensor disc and the showerhead while capacitive sensors arranged on the lower surface of the sensor disc are configured to measure a second distance between the sensor disc and the substrate support. A sum of the first distance, a second distance, and a thickness of the sensor disc corresponds to a measured width of the gap between the showerhead and the substrate support. At least one of the tilt (i.e., level) of the showerhead, the height of the showerhead, and the height of the substrate support can be adjusted based on the measured width of the gap.

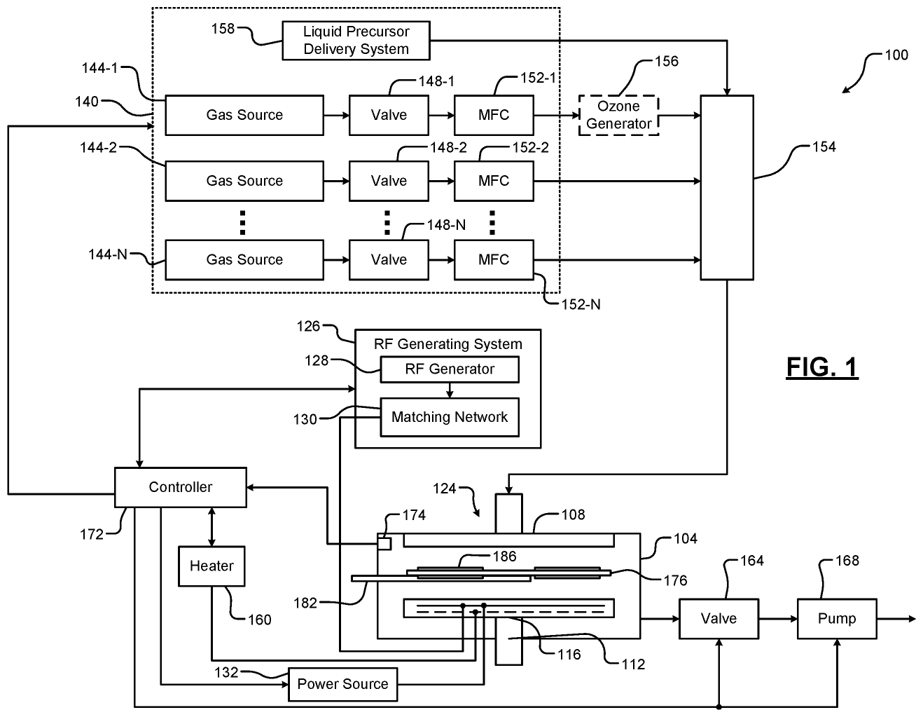

Referring now to FIG. 1, an example of a substrate processing system 100 according to the principles of the present disclosure is shown. While the foregoing example relates to PECVD systems, other plasma-based substrate processing chambers may be used. The substrate processing system 100 includes a processing chamber 104 that encloses other components of the substrate processing system 100. The substrate processing system 100 includes an upper electrode 108 and a substrate support such as a pedestal 112 including a lower electrode 116. A substrate (not shown) is arranged on the pedestal 112 between the upper electrode 108 and the lower electrode 116 during processing. While described below with respect to a single processing chamber 104 and pedestal 112, the principles of the present disclosure may be implemented in systems including multiple processing chambers and processing chambers including multiple processing stations and pedestals, such as a quad station module (QSM).

For example only, the upper electrode 108 may include a showerhead 124 that introduces and distributes process gases. Alternately, the upper electrode 108 may include a conducting plate and the process gases may be introduced in another manner. In some examples, the lower electrode 116 may correspond to a conductive electrode embedded within a non-conductive pedestal. Alternately, the pedestal 112 may include an electrostatic chuck that includes a conductive plate that acts as the lower electrode 116.

A radio frequency (RF) generating system 126 generates and outputs an RF voltage to the upper electrode 108 and/or the lower electrode 116 when plasma is used. In some examples, one of the upper electrode 108 and the lower electrode 116 may be DC grounded, AC grounded, or at a floating potential. For example only, the RF generating system 126 may include one or more RF voltage generators 128 (e.g., a capacitively-coupled plasma RF power generator, a bias RF power generator, and/or other RF power generator) such as an RF generator 128 that generate RF voltages, which are fed by one or more matching and distribution networks 130 to the lower electrode 116 and/or the upper electrode 108. For example, as shown, the RF generator 128 provides an RF and/or bias voltage to the lower electrode 116. The lower electrode 116 may receive power alternatively or additionally from other power sources, such as a power source 132. In other example, an RF voltage may be supplied to the upper electrode 108 or the upper electrode 108 may be connected to a ground reference.

An example gas delivery system 140 includes one or more gas sources 144-1, 144-2, . . . , and 144-N (collectively gas sources 144), where N is an integer greater than zero. The gas sources 144 supply one or more gases (e.g., precursors, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 154. An output of the manifold 154 is fed to the processing chamber 104. For example only, the output of the manifold 154 is fed to the showerhead 124. In some examples, an optional ozone generator 156 may be provided between the mass flow controllers 152 and the manifold 154. In some examples, the substrate processing system 100 may include a liquid precursor delivery system 158. The liquid precursor delivery system 158 may be incorporated within the gas delivery system 140 as shown or may be external to the gas delivery system 140. The liquid precursor delivery system 158 is configured to provide precursors that are liquid and/or solid at room temperature via a bubbler, direct liquid injection, vapor draw, etc.

A heater 160 may be connected to a heater coil 162 arranged in the pedestal 112 to heat the pedestal 112. The heater 160 may be used to control a temperature of the pedestal 112 and the substrate.

A valve 164 and pump 168 may be used to evacuate reactants from the processing chamber 104. A controller 172 may be used to control various components of the substrate processing system 100. For example only, the controller 172 may be used to control flow of process, carrier and precursor gases, striking and extinguishing plasma, removal of reactants, monitoring of chamber parameters, etc. The controller 172 may receive measurement signals indicative of process parameters, conditions within the processing chamber 104, etc. via one or more sensors 174 arranged throughout the substrate processing system 100.

The controller 172 according to the present disclosure is further configured to receive measurement signals from a sensor disc 178 arranged between the showerhead 124 and the pedestal 112. For example, the sensor disc 178 is arranged on an end effector 182, and the end effector 182 positions the sensor disc 178 in a gap between the showerhead 124 and the pedestal 112. Capacitive sensors 186 are arranged on opposing upper and lower surfaces of the sensor disc 178. The capacitive sensors generate the measurement signals based on capacitively sensed distances between the sensor disc 178 and the showerhead 124 and between the sensor disc 178 and the pedestal 112 as described below in more detail. Although described with respect to the distance between the showerhead 124 and the pedestal 112, the principles of the present disclosure can also be applied to measuring the distance between the pedestal 112 and an upper electrode, upper surfaces, etc. of the processing chamber 104.

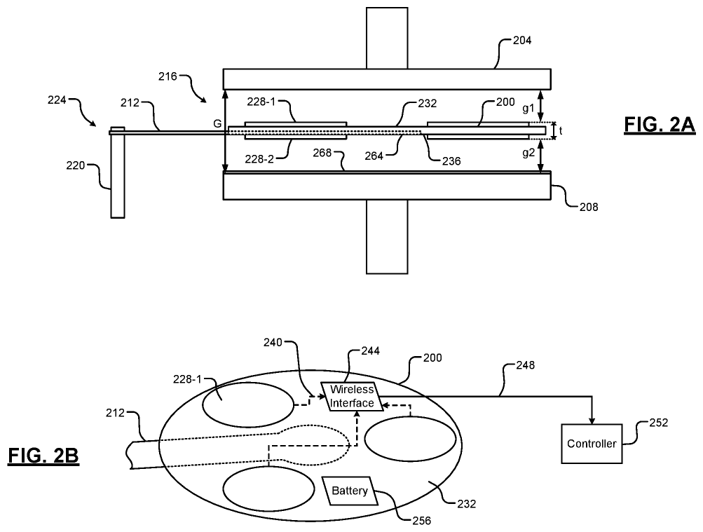

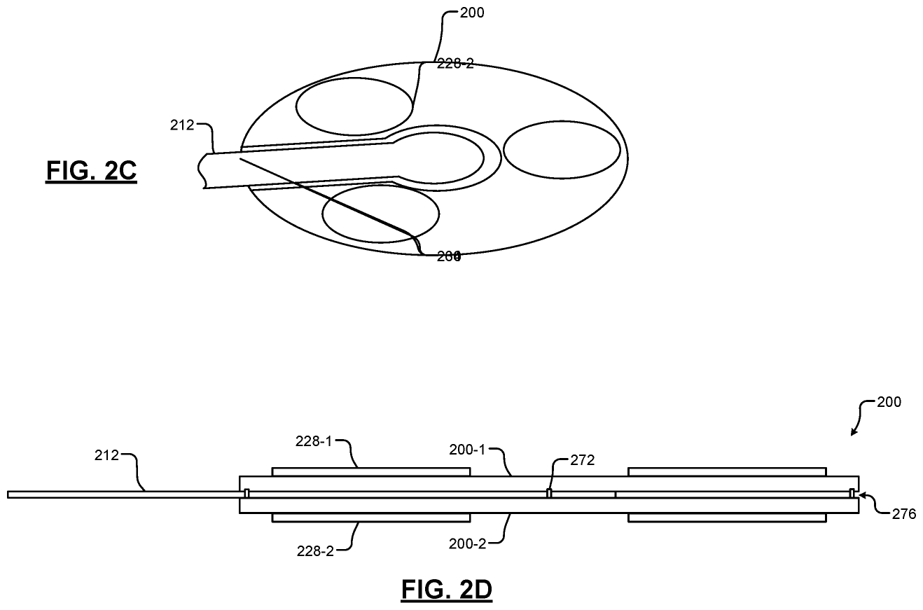

Referring now to FIGS. 2A, 2B, and 2C, an embodiment of a sensor disc 200 according to the present disclosure is shown positioned between a showerhead 204 and a pedestal 208. For example, the sensor disc 200 is arranged on an end effector 212 configured to position the sensor disc 200 within one or more processing stations 216. For example, the end effector 212 may be coupled to a spindle 220 of a mechanical indexer 224 configured to raise and lower the end effector 212 and rotate the end effector 212 between two or more of the processing stations 216. The mechanical indexer 224 may correspond to a mechanical indexer configured to transfer a substrate between different processing stations within a processing chamber or process module (e.g. a multi-station module).

Sensors 228-1 and 228-2 (referred to collectively as sensors 228) are arranged on an upper surface 232 and a lower surface 236, respectively, of the sensor disc 200. The sensors 228 comprise respective sensor electrodes. For example, the sensor electrodes are comprised of a highly conductive material such as copper. In some embodiments, the sensor electrodes may be include a non-conductive coating to prevent corrosion, oxidation, etc. While each of the sensors 228 is shown it include three sensor electrodes, in other embodiments the sensors 228 may include fewer or more sensor electrodes. Spacing and respective sizes of each of the sensor electrodes may also vary. For example, increasing an overall area occupied by the sensors 228 (e.g., increasing diameters of the sensor electrodes) may result in a better sensitivity to detection of gap and tilt.

FIG. 2B shows an isometric view of the upper surface 232 while FIG. 2C shows an isometric view of the lower surface 236. While the sensors 228 are described herein as capacitive sensors, the sensors 228 may be implemented with other suitable types of proximity sensors, such as laser sensors, infra-red sensors, etc. The sensors 228 generate measurement signals 240 (e.g., one or more first measurement signals from the sensors 228-1 and one or more second measurement signals from the sensors 228-2) based on capacitively sensed distances between the sensor disc 200 and the showerhead 204 and between the sensor disc 200 and the pedestal 208.

Although as shown three of the sensors 228 are arranged on each side of the sensor disc 200, in other embodiments fewer (e.g., one or two) or more (e.g., four or more) of the sensors 228 may be provided on each side. For example, as the number of the sensors 228 increases, the distance between the showerhead 204 and the pedestal 208, a tilt of the showerhead 204, etc. can be determined with increased accuracy.

For example, the sensor disc 200 is positioned in a gap G between the showerhead 204 and the pedestal 208. The sensors 228-1 are arranged to generate the measurement signals 240 based on a distance between the upper surface 232 of the sensor disc 200 and the showerhead 204 (e.g., a width of a gap g1). In other words, the sensors 228-1 are upward facing. Conversely, the sensors 228-2 are arranged to generate the measurement signals 240 based on a distance between the lower surface 236 and the pedestal 208 (e.g., a width of a gap g2). In other words, the sensors 228-2 are downward facing.

Accordingly, a width of the gap G corresponds to a sum of the widths of the gaps g1 and g2 and a thickness t of the sensor disc 200 (including the thicknesses of the sensors 228-1 and 228-2) (i.e., G=g1+g2+t). Although as shown in FIG. 2A the sensors 228-1 and 228 protrude upward and downward, respectively, from the sensor disc 200, in embodiments the sensors 228 may be embedded within the sensor disc 200 such that surfaces of the sensors 228 are coplanar (i.e., flush) with the surfaces of the sensor disc 200. Accordingly, in different embodiments, the thickness t may correspond to a distance between the upper surface 232 and the lower surface 236 of the sensor disc 200 (i.e., a thickness of a substrate of the sensor disc 200), a thickness of the sensor disc 200 including the sensors 228-1 and 228-2, etc.

The sensors 228 generate the measurement signals 240 based on a capacitance that varies based on the widths of the gaps g1 and g2. For example, each of the sensors 228 may be configured to generate a reference signal (e.g., an excitation signal having sinusoidal waveform, a square waveform, etc.) at a known amplitude and frequency to excite the sensor 228 (e.g., a lower plate or electrode of the sensor 228). Consequently, a capacitor is formed between the sensor 228 and a surface of a respective one of the showerhead 204 and the pedestal 208. A capacitance of the resulting capacitor as measured by the respective sensor 228 is indicative of the distance between the capacitive sensor and the corresponding surface of the showerhead 204 or the pedestal 208. In other words, capacitances of the capacitive sensors 228-1 indicate respective distances between the capacitive sensors 228-1 and corresponding portions of the showerhead 204. Conversely, capacitances of the capacitive sensors 228-2 indicate respective distances between the capacitive sensors 228-2 and corresponding portions of the pedestal 208.

Accordingly, the measurement signals 240 indicate the capacitances of the sensors 228, which in turn indicate distances between each of the sensors and respective portions of either the showerhead 204 or the pedestal 208. For example, the measurement signals 240 may include digital or analog values of the respective capacitances. In an embodiment, the sensors 228 are configured to measure a variable resistance or reactance indicative of the capacitance, determine the capacitance based on the measured resistance or reactance, and output a digital value (as a respective one of the measurement signals 240) indicating the capacitance.

In some embodiments, the measurement signals 240 are provided to a communication interface, such as a wireless interface 244. The wireless interface 244 transmits the measurement signals 240 (i.e., as wireless signals 248 including the digital value indicating the capacitance) to a device external to the processing station 216, such as a controller 252. For example, the controller 252 corresponds to the controller 172 of FIG. 1. In some embodiments, the wireless interface 244 may transmit the measured signals 240 to the controller 252 in real-time, or near real-time. In other embodiments, the sensor disc 200 may include memory configured to store measurement data corresponding to the measurement signals 240, which may be retrieved when the sensor disc 200 is removed from the processing station 216. In some embodiments, the wireless interface 244 may interact with the memory to transmit measurement data in batches (e.g., in a 4-station chamber, the wireless interface 244 may wait until all four stations are measured before transmitting the measurement data to controller 252) or periodically (i.e. after a set amount of time has lapsed). As shown in FIG. 2B, the sensor disc 200 may include one or more batteries 256. The battery 256 provides power to the sensors 228 and the wireless interface 244. Batch or periodic transmissions may reduce power consumption of the wireless interface 244.

Accordingly, the sensor disc 200 is configured to determine the width of the gap G without being handed off to (i.e., placed on) the pedestal 208. Further, the sensor disc 200 can be rotated through multiple processing stations to measure respective gaps while remaining on the end effector 212, reducing the amount of time required to measure the gaps, reducing particle generation associated with handoffs between the end effector 212 and the pedestal 208, etc.

Further, since the sensor disc 200 remains on the end effector 212, a required clearance between the sensor disc 200, the showerhead 204, and the pedestal 208 may be decreased. In other words, since the end effector 212 does not place the sensor disc 200 on the pedestal 208, the end effector 212 does not need to be lowered and removed from the processing station 216 during measurement. Accordingly, a thickness of the sensor disc 200 including the sensors 228 can be increased (e.g., to 10 or more mm) to reduce a distance between the sensors 228 and the surfaces of the showerhead 204 and the pedestal 208.

For example, for a gap G of approximately (e.g., within 10% of) 17.0 mm and a thickness t of the sensor disc 200 of approximately (e.g., within 10% of) 11.0 mm, each of the gaps g1 and g2 may be reduced to approximately (e.g., within 10% of) 3.0 mm. As such, the thickness t of the sensor disc 200 may be at least 60% (e.g., between 60% and 70%) of the width of the gap G for a gap G less than 20.0 mm. As the width of the gap G increases, the thickness t of the sensor disc 200 may be increased to maintain relatively small gaps g1 and g2 (e.g., less than 5.0 mm, not greater than 3 mm, etc.). Accuracy of the sensors 228 (i.e., accuracy of a relationship between capacitance and distance) is inversely proportional to distance and increases exponentially as distance decreases. Accordingly, increasing the thickness t increases the accuracy of the measurement signals 240.

In some embodiments, the lower surface 236 is flat (e.g., planar) and is supported on the end effector 212. In other embodiments, as shown in FIG. 2C, the lower surface 236 includes a recessed region or socket 260 configured to receive the end effector 212. In other words, a shape of the recessed region 260 is configured to accommodate the end effector 212 such that the end effector 212 is recessed within the lower surface 236 of the sensor disc 200. For example, the recessed region 260 extends from an outer edge to a central region of the sensor disc 200. When the sensor disc 200 is supported on the end effector 212, a lower surface 264 of the end effector 212 may be flush (i.e., coplanar) with the lower surface 236 of the sensor disc 200 (as shown) or slightly (e.g., between 0 and 1.5 mm) above or below the lower surface 236. In this manner, the end effector 212 can more easily position the sensor disc 200 at a midpoint between the showerhead 204 and the pedestal 208 such that the gaps g1 and g2 are approximately the same (e.g., within 5% of each other) regardless of the thickness t of the sensor disc 200.

In some embodiments, the pedestal 208 (or, an upper surface of the pedestal 208) may be comprised of non-metal, such as ceramic. Accordingly, the upper surface of the pedestal 208 may not be configured to form a capacitor with the sensors 228-2. In these embodiments, a metal plate, ring, or other structure (e.g., shown in FIG. 2A as a metal disc 268) may optionally be arranged on the pedestal 208 to provide a metallic surface that can be detected by the sensors 228-2. For example, the metal disc 268 comprises a same material as the showerhead 204 such that equal distances correspond to substantially equal capacitances. The calculation of the gap g2 may include accounting for (e.g., adding) a known thickness of the metal disc 268. In other embodiments, the metal disc 268 may be arranged on the pedestal 208 to reduce the gap g2 and increase the accuracy of the capacitive sensing.

In another embodiment shown in FIG. 2D, the sensor disc 200 includes an upper disc 200-1 and a lower disc 200-2 (referred to collectively as the sensor disc 200). The sensors 228-1 are arranged on or in an upper surface of the upper disc 200-1. Conversely, the sensors 228-2 are arranged on or in a lower surface of the lower disc 200-2. The upper disc 200-1 and the lower disc 200-2 are coupled together (e.g., using a plurality of posts 272) to define a gap 276. The end effector 212 is inserted within the gap 276 to retrieve, support, and transport the sensor disc 200. In this manner, the sensor disc 200 can be configured to minimize the gaps g1 and g2. For example, thicknesses of the upper disc 200-1 and the lower disc 200-2 may be increased to decrease the gaps g1 and g2.

Although as described above the sensor disc 200 includes sensors 228 on both an upper surface and a lower surface, in another embodiment the sensor disc 200 may only include a sensor on one surface (e.g., either on the upper surface or the lower surface). In this embodiment, the sensor disc 200 may first be arranged on the end effector 212 in a first orientation (i.e., with the sensor 228 facing in a first direction, such as upward toward the showerhead 204, to measure the first gap g1. The sensor disc 200 may then be arranged in a second orientation (i.e., flipped) such that the sensor 228 faces an opposite, second direction (i.e., downward toward the pedestal 208) to measure the second gap g2.

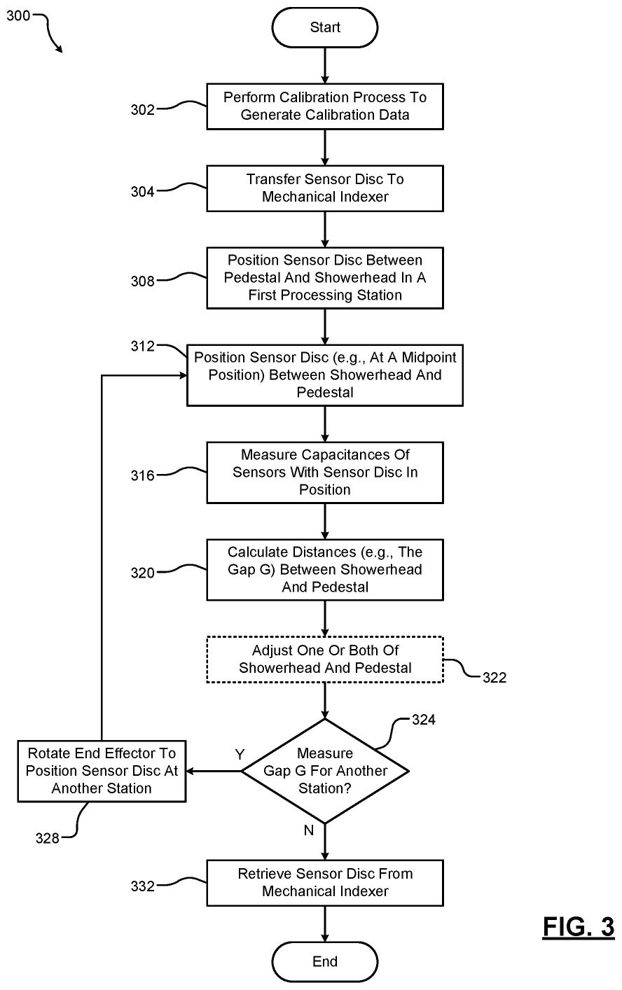

FIG. 3 is an embodiment of a method 300 of determining a distance between a first structure (e.g., a showerhead such as the showerhead 204, an upper surface of a processing chamber, etc.) and a second structure (e.g., a pedestal such as the pedestal 208, a lower surface of a processing chamber, etc.) using a sensor disc (e.g., the sensor disc 200) according to the present disclosure. At 302, the method 300 (e.g., the controller 252) performs a calibration process to generate and store calibration data correlating measured capacitances with distances between the sensors 228 and respective surfaces. For example, the calibration process may be performed at a processing station including a showerhead and pedestal arranged at a known distance, comprised of the same materials as the showerhead 204 and the pedestal 208, etc. In this manner, the method 300 stores data correlating measured capacitances determined by the sensors 228 with actual distances between the sensors 228 and respective surfaces of a showerhead and a pedestal.

At 304, the sensor disc 200 is transferred to the mechanical indexer 224 (e.g., on the end effector 212). For example, the sensor disc 200 is handed off from a transfer robot to the end effector 212 at a loading station of a multi-station process module. At 308, the end effector 212 positions the sensor disc 200 between a showerhead and a pedestal in a first processing station. In some embodiments, the first processing station is the loading station. In other embodiments, the mechanical indexer 224 rotates to position the sensor disc 200 at a processing station different from the loading station.

At 312, the method 300 (e.g., the mechanical indexer 224, responsive to the controller 252) positions the sensor disc 200 at a predetermined position between the showerhead and the loading station. For example only, the predetermined position is a midpoint between the showerhead and the loading station (i.e., a midpoint position). For example, the mechanical indexer 224 is configured to raise and lower the end effector 212 to adjust a vertical position of the sensor disc 200. The method 300 (e.g., the controller 252) determines the midpoint based on relative capacitances of the sensors 228-1 and 228-2 in different vertical positions.

In an embodiment, the mechanical indexer 224 adjusts the sensor disc 200 through different positions (e.g., from a lowermost position to an uppermost position or vice versa) and measures the capacitances of the sensors 228-1 and 228-2 in the different positions. In the lowermost position, capacitances of the sensors 228-2 will be greater (indicating a relatively smaller distance to the pedestal) while capacitances of the sensors 228-1 will be lower (indicating a relatively greater distance to the showerhead). Conversely, in the uppermost position, capacitances of the sensors 228-2 will be lower (indicating a relatively greater distance to the pedestal) while capacitances of the sensors 228-1 will be greater (indicating a relatively lower distance to the showerhead).

In each of the positions, the method 300 determines a difference between the capacitances of the sensors 228-1 (e.g., an average capacitance of two or more of the sensors 228-1) and the capacitances of the sensors 228-2 (e.g., an average capacitance of two or more of the sensors 228-2). The position corresponding to the smallest difference between the capacitances of the sensors 228-1 and 228-2 corresponds to the midpoint between the showerhead and the pedestal (e.g., assuming materials of the surfaces of the showerhead and the pedestal are the same). In other words, the method 300 may assume that capacitances measured by the sensors 228-1 and 228-2 will be substantially the same when the sensor disc 200 is positioned at the midpoint since distances between opposing surfaces of the sensor disc 200 and the respective surfaces of the showerhead and the pedestal would also be the same.

At 316, the method 300 measures capacitances of each of the sensors 228-1 and 228-2 (e.g., with the sensor disc 200 in the predetermined position, such as the midpoint position). For example, as described above, the sensors 228 generate measurement signals 240 indicating the measured capacitances, which are transmitted as digital values to the controller 252. At 320, the method 300 (e.g., the controller 252) calculates distances (e.g., widths of the gap G) between respective portions of the showerhead and the pedestal based on the capacitances. For example, the controller 252 calculates the distances based on the measured capacitances and the stored calibration data correlating capacitance to distance for each of the sensors 228. The controller 252 may store the calculated distances for retrieval, display, etc.

Although, as described, the method 300 determines the distances with the sensor disc 200 in the midpoint position, in other embodiments the capacitances and distances can be determined without determining the midpoint position, with the sensor disc 200 in positions other than the midpoint position, etc. For example, the mechanical indexer 224 may maintain a same nominal or calibrated position during the process and rotate the sensor disc 200 through multiple processing stations to measure distances between respective showerheads and pedestals without adjusting a vertical position of the sensor disc 200.

At 322, the showerhead and/or the pedestal of one or more of the processing stations may optionally be adjusted based on the measured gap G. The measured gap G may indicated that the showerhead is tilted, a distance between the showerhead and the pedestal is greater than or less than a desired distance, etc. In some embodiments the adjustment is performed manually (e.g., by accessing an interior of the process module during servicing). In other embodiments, the adjustment may be performed automatically by raising or lowering one or both of the showerhead and the pedestal using respective actuators responsive to the controller 252. The adjustment may be iteratively performed until the measured gap corresponds to the desired gap. For example, the method 300 may repeat 316, 320, and 322 until the desired gap is achieved.

At 324, the method 300 determines whether to measure the gap G for another processing station. If true, the method 300 continues to 328. If false, the method 300 continues to 332. At 328, the method 300 (e.g., the mechanical indexer 224) rotates the end effector 212 to position the sensor disc 200 at another processing station and continues to 312.

At 332, the sensor disc 200 is retrieved from the mechanical indexer 224. For example, the sensor disc 200 is returned to the loading station and retrieved using a transfer robot. The sensor disc 200 may be stored within the substrate processing system (e.g., at a buffer station within a vacuum transfer module or equipment front end module), retrieved from the substrate processing system, transferred to another multi-station module, etc. One or more steps in method 300 may be omitted or rearranged while still achieving the objective of determining the distance between a showerhead (e.g., the showerhead 204) and a pedestal (e.g., the pedestal 208). For example, the calibration step (302) may be omitted in some events.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A sensor disc configured to measure a gap between a first structure and a second structure in a processing chamber of a substrate processing system, the sensor disc comprising:
an upper surface;
at least one first capacitive sensor arranged on the upper surface of the sensor disc, wherein the at least one first capacitive sensor is configured to generate a first measurement signal indicative of a first distance between the upper surface of the sensor disc and the first structure;
a lower surface; and
at least one second capacitive sensor arranged on the lower surface of the sensor disc, wherein the at least one second capacitive sensor is configured to generate a second measurement signal indicative of a second distance between the lower surface of the sensor disc and the second structure.

2. The sensor disc of claim 1, wherein the at least one first capacitive sensor includes three capacitive sensors arranged on the upper surface of the sensor disc.

3. The sensor disc of claim 1, wherein the at least one second capacitive sensor includes three capacitive sensors arranged on the lower surface of the sensor disc.

4. The sensor disc of claim 1, wherein the at least one first capacitive sensor is configured to (i) form a first capacitor with the first structure and (ii) generate the first measurement signal based on a first capacitance of the first capacitor.

5. The sensor disc of claim 4, wherein the at least one second capacitive sensor is configured to (i) form a second capacitor with the second structure and (ii) generate the second measurement signal based on a second capacitance of the second capacitor.

6. The sensor disc of claim 1, further comprising a recessed region defined in the lower surface of the sensor disc, wherein the recessed region extends from an outer edge to a central region of the sensor disc.

7. A system comprising the sensor disc of claim 1 and further comprising a controller configured to (i) receive the first measurement signal and the second measurement signal and (ii) calculate a width of the gap between the first structure and the second structure based on the first measurement signal and the second measurement signal.

8. The system of claim 7, wherein the controller is configured to calculate the width of the gap based on the first distance, the second distance, and a thickness of the sensor disc.

9. The system of claim 8, wherein the controller is configured to calculate the width of the gap further based on stored data (i) correlating a first capacitance formed between the at least one first capacitive sensor and the first structure to the first distance and (ii) correlating a second capacitance formed between the at least one second capacitive sensor and the second structure to the second distance.

10. The sensor disc of claim 1, wherein the first structure is a showerhead and the second structure is a pedestal.

11. A system configured to measure a gap between a first structure and a second structure in a processing chamber of a substrate processing system, the system comprising:
a sensor disc including at least one first capacitive sensor arranged on an upper surface of the sensor disc and at least one second capacitive sensor arranged on a lower surface of the sensor disc; and
a controller configured to
receive, from the at least one first capacitive sensor, a first measurement signal indicative of a first distance between the upper surface of the sensor disc and the first structure,
receive, from the at least one second capacitive sensor, a second measurement signal indicative of a second distance between the lower surface of the sensor disc and the second structure, and
calculate a width of the gap between the first structure and the second structure based on the first measurement signal and the second measurement signal.

12. The system of claim 11, wherein the controller is configured to calculate the width of the gap based on the first distance, the second distance, and a thickness of the sensor disc.

13. The system of claim 12, wherein the controller is configured to calculate the width of the gap further based on stored data (i) correlating a first capacitance formed between the at least one first capacitive sensor and the first structure to the first distance and (ii) correlating a second capacitance formed between the at least one second capacitive sensor and the second structure to the second distance.

14. The system of claim 11, wherein a recessed region is defined in the lower surface of the sensor disc, and wherein the recessed region extends from an outer edge to a central region of the sensor disc.

15. The system of claim 14, further comprising a mechanical indexer including an end effector, wherein the recessed region is configured to receive the end effector.

16. A method for measuring a gap between a first structure and a second structure in a processing chamber of a substrate processing system, the method comprising:
arranging a sensor disc on an end effector;
positioning the sensor disc in the gap between the first structure and the second structure;
determining, using the sensor disc, (i) a first distance between an upper surface of the sensor disc and the first structure and (ii) a second distance between a lower surface of the sensor disc and the second structure; and
calculating a width of the gap between the first structure and the second structure based on the first distance and the second distance.

17. The method of claim 16, wherein the sensor disc includes at least one first capacitive sensor arranged on an upper surface of the sensor disc and at least one second capacitive sensor arranged on a lower surface of the sensor disc.

18. The method of claim 17, further comprising:
generating, using the at least one first capacitive sensor, a first measurement signal indicative of the first distance between the upper surface of the sensor disc and the first structure;
generating, using the at least one second capacitive sensor, a second measurement signal indicative of the second distance between the lower surface of the sensor disc and the second structure; and
calculating the width of the gap between the first structure and the second structure based on the first measurement signal, the second measurement signal, and a thickness of the sensor disc.

19. The method of claim 18, further comprising:
generating the first measurement signal based on a first capacitance formed between the at least one first capacitive sensor and the first structure; and
generating the second measurement signal based on a second capacitance formed between the at least one second capacitive sensor and the second structure.

20. The method of claim 16, wherein the sensor disc includes a recessed region defined in the lower surface of the sensor disc, wherein the recessed region extends from an outer edge to a central region of the sensor disc, and wherein arranging the sensor disc on the end effector includes arranging the recessed region of the sensor disc on the end effector.

21. The method of claim 16, wherein positioning the sensor disc includes positioning the sensor disc at a midpoint between the first structure and the second structure.

22. The method of claim 16, wherein the first structure is a showerhead and the second structure is a pedestal.
